(19) United States
(12) Patent Application Publication
(10) Pub. No.: US 2026/0319046 A1
(43) Pub. Date: Oct. 15, 2026

(54) METHOD OF IMAGE GENERATION BY MRI USING EPI

(71) Applicant: OXFORD UNIVERSITY INNOVATION LIMITED, Oxford (GB)

(72) Inventor: Wenchuan WU, Oxford (Oxfordshire) (GB)

(21) Appl. No.: 19/484,895

(22) PCT Filed: May 17, 2024
(86) PCT No.: PCT/GB2024/051285

§ 371 Date: Nov. 17, 2025

(30) Foreign Application Priority Data
May 18, 2023 (GB) 2307480.0

(51) Int. Cl. G01R 33/561; G01R 33/48; G01R 33/56

(52) U.S. Cl. CPC G01R 33/5616; G01R 33/4828; G01R 33/5608

(57) ABSTRACT

According to examples of the invention, there is provided a method of image generation using magnetic resonance imaging, MRI, with echo-planar imaging, EPI. The method comprises transmitting a RF pulse (411) to a subject in a static magnetic field in the presence of an applied spatial magnetic field gradient; receiving magnetic resonance, MR, signals; sampling the received MR signals to acquire a plurality of temporarily adjacent EPI volumes and generating a k space map (601) for the plurality of EPI volumes by: applying an oscillating readout gradient (417) over each of the plurality of EPI volumes to obtain readout data along a readout axis; and applying a phase encoding gradient (415), while applying the oscillating readout gradient (417), such that trajectory lines of readout data for each of the plurality of EPI volumes are interleaved in k space using a periodic rewinding pattern along a phase encoding axis. The method comprises dividing the generated k space map (601) into a plurality of k space sub-maps (603a, 603b, 603c), each of the plurality of k space sub-maps (603a, 603b, 603c) associated with one of the plurality of EPI volumes and applying an optimisation function utilising shared information across the plurality of k space sub-maps (603a, 603b, 603c) to jointly reconstruct k space data; and generating an image (621) based on the jointly reconstructed k space data.

### TECHNICAL FIELD

Aspects of the invention relate to image generation using magnetic resonance imaging, MRI, with echo-planar imaging, EPI. Aspects of the invention relate to a method, a system, and a computer program.

### BACKGROUND

Echo planar imaging (EPI), is utilised in functional and diffusion MRI (fMRI, dMRI) studies. However, given its low bandwidth along a phase encoding direction, EPI imaging is susceptible to inhomogeneity in the B₀ field (the static, or main, magnetic field), which may result in image distortion. Such B₀ field inhomogeneity may rise due to inherent properties of the magnet or hardware, or from the patient (e.g., subject motion and/or susceptibility difference between different types of tissue).

In some cases, static B₀ field distortions can be corrected in post-processing, for example, using a separately acquired (B₀) field map. However, this acquired field map cannot capture dynamic B₀ variation: for example, subject motion, gradient heating, respiration and eddy currents. These uncompensated field fluctuations may result in temporally varying image distortions that may obscure subtle activation signals in fMRI studies and lead to biased model fitting in dMRI studies.

Various methods have been proposed for the correction of dynamic EPI distortions, such as navigator acquisition techniques to acquire data for B₀ field map estimation for each EPI image volume. However, these techniques may increase scan time and reduce temporal resolution, and may also increase echo time (TE) compared to a standard EPI sequence. Other approaches may acquire additional calibration data, and/or additional hardware.

In addition, navigator-free dynamic B₀ field mapping methods may utilise the phase difference of EPI images for B₀ field map estimation. In examples, this may utilise conventional EPI readout that acquires a single echo. However, such methods are reliant on phase unwrapping and temporal stability of static offset φ0 (B₁ field inhomogeneity, where B₁ is perpendicular to main field, B₀). Other methods utilise multi-echo EPI (ME-EPI), wherein multiple EPI images may be acquired following each excitation at different Time to Echo, TEs. In such methods, B₀ field map calculation can be performed from a single EPI readout, which improves robustness of the estimation against dynamic EPI distortions, for example, as arising from subject motion or respiration.

However, these ME-EPI methods have limitations in spatial resolution, as later images of the sequence have a long TE, and a long echo time difference required to accommodate multiple echoes can lead to significant phase wrapping (i.e. phase shifts beyond +/−π radians that wrap around to smaller phase values), particularly in regions with strong field inhomogeneity and at ultra-high fields, which can be challenging to unwrap in post processing. Whilst parallel imaging techniques can mitigate these limitations by under-sampling acquired k space for each EPI image, further limitations arise, e.g. such as low signal to noise ratio, SNR, due to the under sampling factor required to achieve high spatial resolution, particularly for later echoes (long TE).

In clinical use, MRI scans mainly detect signals from protons, which can be detected from both water or fat. Imaging of fat, in particular, can be potentially used for quantification of disease severity due to abnormal fat deposition. However, if the organs are moving during an MRI scan, accurate quantification of fat can be challenging.

Due to its very short T1 relaxation time, a fat signal typically appears very bright in the image that can obscure underlying pathology, which can be challenging for EPI acquisition. The low bandwidth along the phase encoding direction in EPI may cause the fat signal to shift along this direction and overlap with tissue signal, resulting in chemical shift artefact. Conventional methods of chemical shift based water-fat separation methods using EPI are sensitive to patient motion, and therefore cannot provide accurate quantification of fat in generated images.

There is a need to address and/or mitigate at least some of the disadvantages of image generation in MRI using EPI, as set out above.

The above information is presented as background information only to assist with an understanding of the present disclosure. No determination has been made, and no assertion is made, as to whether any of the above might be applicable as prior art with regard to the present invention.

### SUMMARY

It is an aim of certain examples of the present disclosure to address, solve and/or mitigate, at least partly, at least one of the problems and/or disadvantages associated with the related art, for example at least one of the problems and/or disadvantages described. It is an aim of certain examples of the present disclosure to provide at least one advantage over the related art.

Certain examples of the present disclosure provide a magnetic resonance imaging (MRI) method for generating images using echo-planar imaging (EPI). Certain examples of the present disclosure provide a method for distortion correction of images using EPI. Certain examples of the present disclosure provide a method for generating water-fat images using EPI.

The present invention is defined in the independent claims. Further advantageous features are defined in the dependent claims.

Embodiments or examples disclosed in the description and/or figures falling outside the scope of the claims are to be understood as examples useful for understanding the present invention.

According to an aspect of the invention, there is provided a method of image generation using magnetic resonance imaging, MRI, with echo-planar imaging, EPI. The method comprises transmitting a RF pulse to a subject in a static magnetic field in the presence of an applied spatial magnetic field gradient; receiving magnetic resonance, MR, signals; sampling the received MR signals to acquire a plurality of temporarily adjacent EPI volumes and generating a k space map for the plurality of EPI volumes by: applying an oscillating readout gradient over each of the plurality of EPI volumes to obtain readout data along a readout axis; and applying a phase encoding gradient, while applying the oscillating readout gradient, such that trajectory lines of readout data for each of the plurality of EPI volumes are interleaved in k space using a periodic rewinding pattern along a phase encoding axis. The method comprises dividing the generated k space map into a plurality of k space sub-maps, each of the plurality of k space sub-maps associated with one of the plurality of EPI volumes and applying an optimisation function utilising shared information across the plurality of k space sub-maps to jointly reconstruct k space data; and generating an image based on the jointly reconstructed k space data.

According to a further aspect of the invention, a method for of image generation using magnetic resonance imaging, MRI, using with echo-planar imaging, EPI, is provided. The method comprises transmitting a RF pulse to a subject in a static magnetic field in the presence of an applied spatial magnetic field gradient and transmitting a second RF pulse to the subject in the static magnetic field in the presence of an applied spatial magnetic field gradient. The method comprises receiving magnetic resonance, MR, signals and sampling the received MR signals to acquire a plurality of temporarily adjacent EPI volumes. The method comprises generating a k space map for the plurality of EPI volumes by: applying an oscillating readout gradient over each of the plurality of EPI volumes to obtain readout data along a readout axis; and applying a phase encoding gradient, while applying the oscillating readout gradient, such that trajectory lines of readout data for each of the plurality of EPI volumes are interleaved in k space using a periodic rewinding pattern along a phase encoding axis. The method further comprises applying an optimisation function utilising shared information (e.g. between, or representative of, the EPI volumes). The optimisation may be in image space or k space. When in k space (e.g. the generated k space map) the optimization is to jointly reconstruct k space data, and generating an image (e.g. generating a water image and/or a fat image) based on the jointly reconstructed k space data.

According to a further aspect of the invention, there is provided a system for image generation for magnetic resonance imaging, MRI, using echo-planar imaging, EPI, the system comprising an MRI device and computing device, and the system configured to perform the above-described methods.

According to a further aspect of the invention, there is provided a computer program comprising instructions which, when the program is executed by a computer or processor, causes the computer or processor to carry out the above-described methods.

Other aspects, advantages and salient features of the invention will become apparent to those skilled in the art from the following detailed description taken in conjunction with the accompanying drawings.

### BRIEF DESCRIPTION OF THE DRAWINGS

Embodiments, examples and aspects of the disclosure are further described hereinafter with reference to the accompanying drawings, in which:

FIG. 1 illustrates an example MRI system;

FIG. 2a illustrates conventional single-shot EPI sampling in the ky-t space, k space and corresponding sequence diagrams;

FIG. 2b illustrates conventional multi-echo, ME, EPI sampling in the ky-t space, k space and corresponding sequence diagrams, respectively;

FIG. 2c illustrates a conventional under-sampled ME-MRI in the ky-t space, k space and corresponding sequence diagrams;

FIG. 3 illustrates a flowchart of a method for correction of image distortion in MRI using EPI imaging in accordance with an example of the present disclosure;

FIG. 4 illustrates sampling in the ky-t space, k space and corresponding sequence diagrams illustrating an ME-rEPI trajectory in accordance with an example of the present disclosure;

FIG. 5 illustrates ME-rEPI trajectories according to further examples of the present disclosure;

FIG. 6 illustrates a diagram illustrating joint reconstruction and distortion correction pipeline for ME-rEPI, according to an example of the present disclosure;

FIG. 7 illustrates an example of application of the low-rank structured matrix recovery for joint reconstruction based on low-rank Hankel structured matrix recovery, according to an example of the present disclosure;

FIG. 8a illustrates a pulse sequence diagram for gradient-echo rEPI, in accordance with examples of the present disclosure;

FIG. 8b illustrates a pulse sequence diagram for spin-echo rEPI, in accordance with examples of the present disclosure;

FIG. 9 illustrates field and magnitude maps of an axial slice acquired using conventional GRE based field mapping method, and ME-rEPI based field mapping method according to an example of the present disclosure;

FIGS. 10a and 10b illustrate a comparison between a conventional gradient multi-echo approach and ME-rEPI according to an example of the present disclosure;

FIG. 11 illustrates a comparison between conventional fat suppression method and rEPI based water fat separation according to an example of the present disclosure; and

FIG. 12 illustrates a comparison of conventional fat suppression and water-fat imaging using single-shot rEPI according to an example of the present disclosure.

### DETAILED DESCRIPTION

The following description of examples of the present disclosure, with reference to the accompanying drawings, is provided to assist in a comprehensive understanding of the present invention, as defined by the claims. The description includes various specific details to assist in that understanding but these are to be regarded as merely exemplary. Accordingly, those of ordinary skill in the art will recognize that various changes and modifications of the examples described herein can be made without departing from the scope of the invention.

The same or similar components may be designated by the same or similar reference numerals, although they may be illustrated in different drawings.

Detailed descriptions of techniques, structures, constructions, functions or processes known in the art may be omitted for clarity and conciseness, and to avoid obscuring the subject matter of the present invention.

The terms and words used herein are not limited to the bibliographical or standard meanings, but, are merely used to enable a clear and consistent understanding of the invention.

Throughout the description and claims of this specification, the words “comprise”, “include” and “contain” and variations of the words, for example “comprising” and “comprises”, means “including but not limited to”, and is not intended to (and does not) exclude other features, elements, components, integers, steps, processes, operations, functions, characteristics, properties and/or groups thereof.

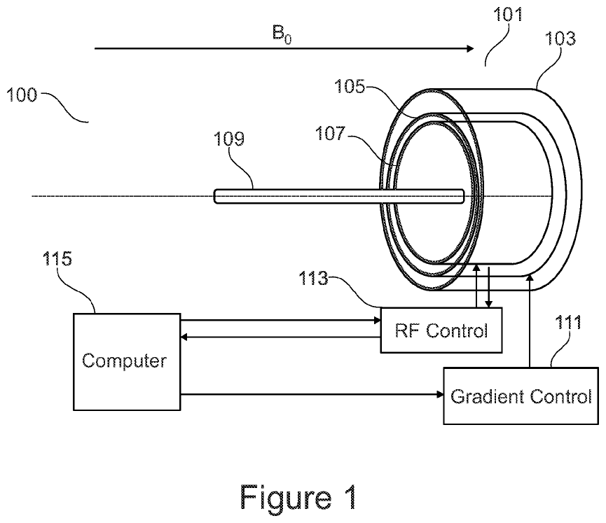

FIG. 1 illustrates an example Magnetic Resonance Imaging, MRI, system 100, which may be utilised for image generation in accordance with examples of the present disclosure. Whilst example components of an MRI system are herein described, it will be appreciated that such hardware elements are described by way of example so as to more clearly define the present disclosure and examples herein, and are not intended to be limiting. That is, an example MRI system described with reference to the detailed description may comprise one or more further components, or elements, to those described.

Referring to FIG. 1, and MRI system 100, a subject (i.e. patient) is placed onto a table 109. The table 109, when in use (i.e. when performing a scan) is positioned within a bore of a main body 101 of the MRI system. The main body 101 comprises a primary magnet 103, a plurality of gradient coils 105, and at least one radio frequency, RF, coil 107. The plurality of gradient coils 105 and at least one radio frequency coil 107 are placed within the bore of the primary (main) magnet 103 within the main body 101 when in use i.e. performing a scan. It will be appreciated that the at least one RF coil may be located outside of the bore when not in use. Within FIG. 1, for clarity in description, the described components are illustrated in a simplified view; however, it will be appreciated that these will be arranged in one or more known arrangements within the main body 101 of said MRI system 100.

The primary magnet 103, when activated, e.g., by application of a current to a coil provided therein, produces a static, or main, magnetic field, B₀. Referring to FIG. 1, the direction of B₀, that is, the direction through the bore of primary magnet 103, defines the direction of the longitudinal axis. In an example, this may be termed a z-axis direction.

The MRI system 100, within the main body 101, comprises a plurality of gradient coils 105. The plurality of gradient coils 105 may comprise x-gradient, y-gradient and z-gradient coils. A current may be passed through one or more of the gradient coils, the net effect of which creating a secondary, or gradient, magnetic field. The gradient magnetic field provides a linear variation in magnetic field intensity (i.e. net magnetic field strength of the static and gradient magnetic field) in one or more directions. Application of current to one or more gradient coils may be provided by gradient control (or controller) 111, and/or with overall control by computer 115.

The MRI system 100 comprises a radio frequency, RF, coil 107, controlled by RF control 113, RF control 113 comprises means for receiving (or sensing) and transmitting RF signals (e.g. an RF receiver and RF transmitter), i.e., by way of applying a current to RF coil 107 to generate an RF pulse. The RF control 113 is controlled by computer 115 (computing device), which instructs (or controls) generation of the RF pulse. Data (e.g. as received by RF control 113) is provided back to computer 115. The one or more RF pulses are applied for a short time duration so as to flip a net magnetization of nuclei spin (i.e. into a transverse axis).

A computer 115, (or otherwise, control system, controller or processor) may provide overall control of MRI system, and may control the RF control 113 and gradient control 111. In examples, RF control 113 and gradient control 111 may be comprised separately, or, in other examples, as part of computer 115. The computer 115 may comprise a computer-readable memory having computer executable instructions stored therein which, when executed by the computer, perform a method according to an embodiment of the invention.

MRI imaging is based on precession of nuclei about the B₀ axis (i.e. along the longitudinal axis) corresponding to the static (main) magnetic field. Application of an RF pulse generates an additional magnetic field, B₁, that tilts the net magnetisation of the nuclei out of alignment with the B₀ field. In other words, components of the magnetisation at least partially align (or tip into) the transverse plane. When the net magnetisation is tilted from an equilibrium position (i.e. when aligned with the longitudinal), the net magnetisation in the transverse plane will start to decay, and the nuclei process around the B₀ axis (nuclear magnetic resonance). MRI imaging utilises MR signals, that is, the electrical current, induced in an RF receiver by resonance of the nuclei spin following application of the RF pulse.

The received MR signals are acquired in the frequency domain. To obtain an MR image, spatial frequencies of MR signals—that is, as encoded by the application of a gradient magnetic field—are acquired, or represented, along x, y and/or z directions in k-space. K space data is obtained (or sampled) from the MR signal, using a defined method (trajectory) through which k space is filled. Finally, an MRI image is recovered from generated k-space using Fourier transforms. That is, an MRI image (e.g. a final image, or clinical scan) can be generated (or converted) from k space using Fourier transforms (e.g. 1-D, 2-D, 3-D FT).

Echo-Planar imaging, EPI, acquires data in k space based on a small number of excitations (e.g. RF pulses). At a time following transmission of an RF pulse, the MR signals are sampled. One or more RF pulses may be transmitted during an imaging sequence, each RF pulse being applied at TR (repetition time). That is, TR may refer to the time between successive RF pulses. A time duration from the applied RF pulse to the time of the sampling at the k-space centre of one image, or EPI, volume (that is the peak, or centre, of the received signal at the RF coil), which is termed time to echo, or TE. Each sampling of the MR signals acquires k space data, and is termed one EPI volume. This may also be termed an EPI image, or echo. In single-shot EPI images, all k-space data is acquired at once (i.e. following a single RF-excitation pulse). In multi-shot EPI images, k space data may be acquired following one or more (a small number) of excitations (or RF pulses). That is, conventionally, the multiple shots (multi-shot) EPI images preserve the same TE (e.g. such that in combination, there will be no TE related contrast difference).

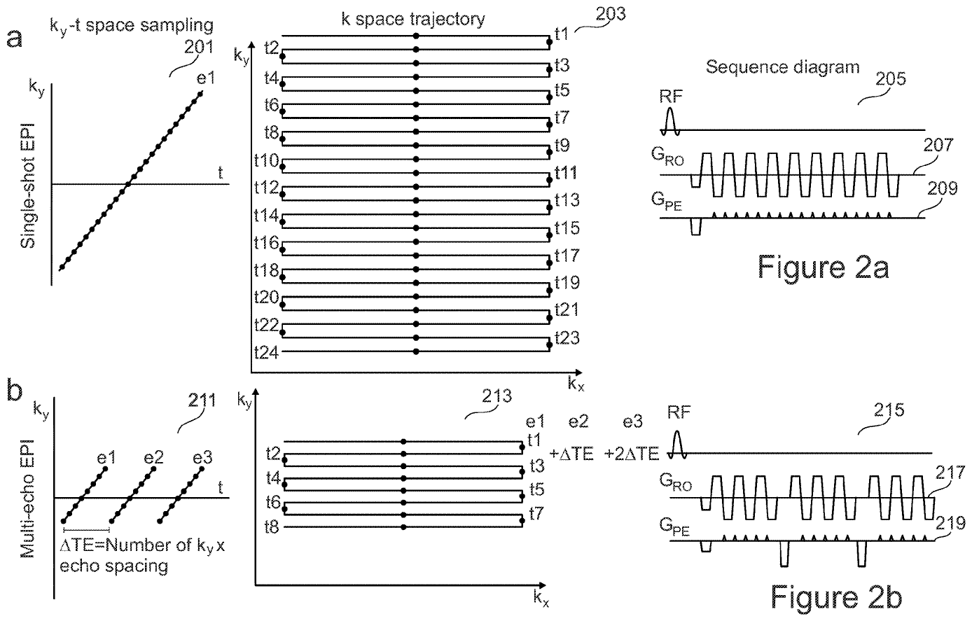

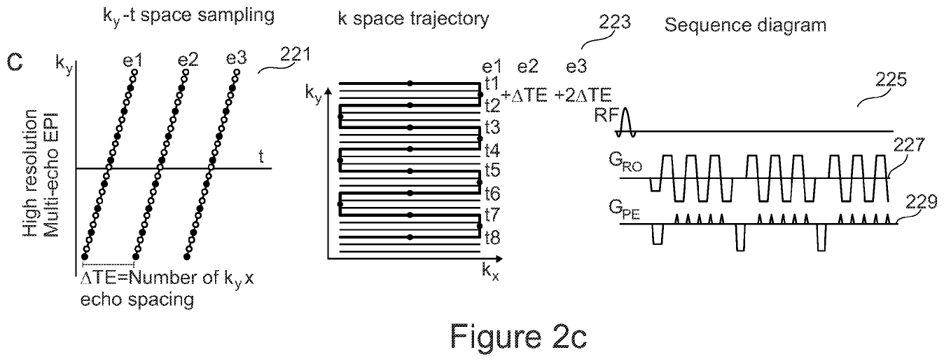

FIG. 2a illustrates conventional single-shot EPI sampling in the ky-t space, k space and corresponding sequence diagrams, respectively. FIG. 2b illustrates conventional multi-echo, ME-EPI (echo 1, e1, echo 2, e2, echo 3, e3) sampling in the ky-t space, k space and corresponding sequence diagrams, respectively. FIG. 2c illustrates ME-MRI (3 echoes) that is under-sampled. For each of FIGS. 2a-2c, the ky-t space, k space, and sequence diagrams represent, or illustrate, the same sampling of MR signals. That is, k space and k_{y}-t space represent the signals obtained by application of the RF pulse, and gradient control sequence, as shown in the respective sequence diagrams.

As illustrated in FIG. 2a, conventional single-shot sampling EPI acquires one echo (sampled MR signals) corresponding to a single straight line in ky-t space 201.

Referring now to sequence diagram 205, the MR signals are sampled whilst applying a frequency encoding gradient 207 in a plane (e.g. the x axis) of the selected slice (MR signals), thereby frequency encoding the signals. The frequency encoding gradient 207 is applied by one or more of the gradient coils 105, and may be provided as an oscillating signal 207 (i.e. at a changing polarity). That is, each edge of the frequency encoding gradient 207 controls the gradient to obtain sampled signals of an individual sample (or dot) in ky-t space, 201, and corresponds to a range, or line, of signals (e.g. t1) along the x axis in k-space 203.

Referring again to sequence diagram 205, a phase encoding gradient, 209 is applied in a plane (e.g. y axis) of the selected slice. The phase encoding gradient 209 is applied by one or more of the gradient coils 105. The magnitude at which the phase encoding gradient is applied dephases the spin of the nuclei (thus phase encoding the signal). In EPI imaging application of the phase encoding gradient (i.e. being applied at a magnitude) is performed so as to spatially encode a phase difference between successive k_{y} readouts in k space 203. For example, each application of the phase encoding gradient is represented as an EPI blip in k space, wherein, these may be termed standard, or regular, EPI blips (at a same magnitude). For example, each line (t1, t2 [ . . . ]), in k space differs based on application of the phase encoding gradient (e.g. over time of acquisition). That is, each application of the phase encoding gradient, such as shown in FIGS. 2a-2c in phase encoding sequence at 209, 219, may be referred to as EPI blips as described. In the example shown, each application (or blip) of the phase encoding gradient 209 may be synchronised on a rising/falling edge of the frequency encoding gradient, during sampling of the MR signals, defining the trajectory in k space 203.

FIG. 2b illustrates an example of ME-MRI sampling, where multi-echo MRI acquires multiple EPI images, or echoes, sequentially, in one TR (e.g. following one RF pulse). In the example of FIG. 2b, 3 echoes (EPI images) are acquired. In ky-t space, 211, these multiple EPI images correspond to several straight lines in ky-t space, 211, separated by an echo time difference ΔTE. Therefore, in an example, taking the echo time of the first EPI volume to be TE, the echo times of the second and the third EPI volumes are TE+ΔTE, and TE+2*ΔTE, respectively. That is, in some examples, it will be appreciated that TE may be equal, or longer, than ΔTE.

Considering k space, 213, this is filled by sampling first echo, e1, by application of the trajectory defined by the application of frequency and phase encoding gradients (shown in the corresponding sequence diagram 215). Subsequently, k space is filled from sampling echo 2, e2, at further TE, and echo e3, at further TE (i.e. TE+2*ΔTE).

As shown in FIG. 2b, an echo time difference, ΔTE, for conventional ME-MRI is determined by the number of k_{y} encoding lines for each EPI image and the EPI echo spacing. That is, a time between sampling from echo, e1, and echo, e2, is defined by (or coupled to) the number of k_{y} sampling points (e.g. ky encoding lines). In other words, as shown in the example of FIG. 2b, the sampling for echo e2 is not started until the sampling (i.e. the obtained k space trajectory) of echo e1 is completed.

Similarly to FIG. 2b, FIG. 2c illustrates ME-MRI (3 echoes), but illustrates an under-sampling of k space (high-resolution multi-echo EPI). In other words, FIG. 2c corresponds to FIG. 2b, but with an increased k_{y} trajectory gradient. The trajectory through k space is applied with a different magnitude (i.e. larger) phase encoding gradient in the k_{y} axis than FIG. 2b. That is, in FIG. 2c, in comparison to FIG. 2b, each application of the phase encoding gradient is applied at a larger magnitude to those applied within FIG. 2b, and as illustrated by EPI blips in k space. Again, these may be termed standard, or regular EPI blips. This results in sampling of each echo, e1-e3, extending over a larger extent of k space, 225 in FIG. 2c as compared to FIG. 2b.

Conventionally, due to the sequential acquisition of multiple EPI images, the achievable resolution of ME-EPI is intrinsically limited. As the later EPI images are acquired after the completion of earlier EPI images, the TEs of later EPI images are fairly long, which results in a lower SNR (Signal to Noise Ratio) due to T2* signal decay. This can be significant for a high resolution scan with a large number of k_{y} encoding lines for each EPI image. A high resolution scan is associated with a long echo time difference, ΔTE, which can cause a significant wrapping effect in phase evolution Δφ(r), which is the phase difference between individual EPI images, particularly when field inhomogeneity is strong (e.g. at tissue-air interface, and/or ultra high field).

Parallel imaging techniques allow a higher spatial resolution for ME-EPI by sampling a larger k-space coverage with under-sampled acquisition, as shown in in FIG. 2c. Here, the total number of ky encoding lines are unchanged from FIG. 2b, and therefore TE, and echo time difference, ΔTE. However, parallel imaging reconstructions are prone to SNR penalties, particularly for later echoes with longer TEs, which can degrade phase map accuracy.

It is therefore desirable to address and/or mitigate at least some of the above-detailed limitations by means of an improved method for distortion correction in MRI using EPI, by means of the examples described in the present disclosure.

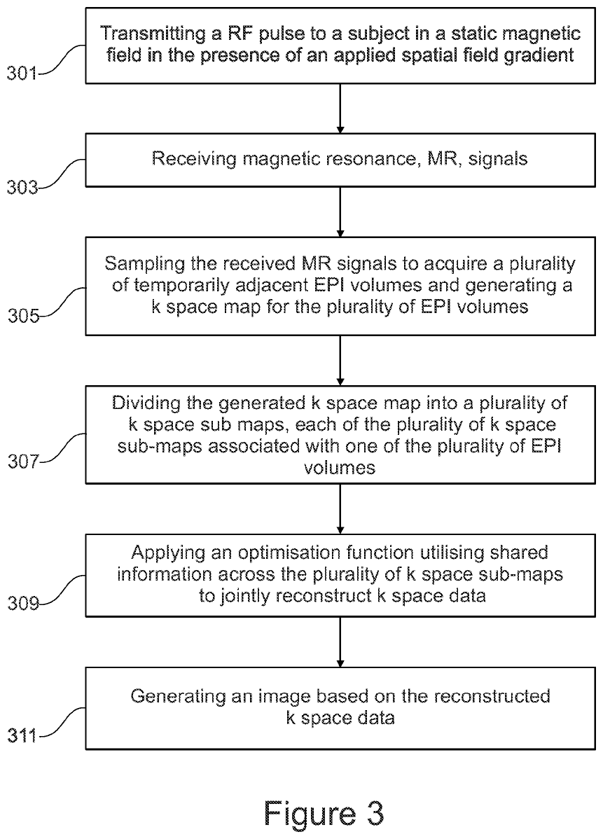

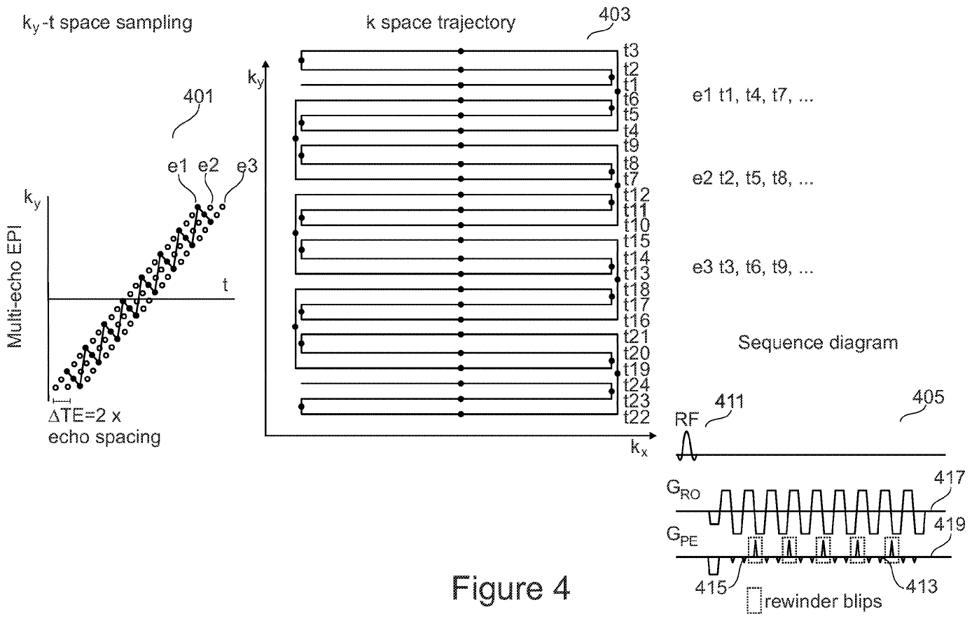

FIG. 3 illustrates a flowchart of method for image generation in MRI using EPI imaging, according to an example of the present disclosure. FIG. 4 illustrates ky-t space, k space and corresponding sequence diagrams illustrating an ME-rEPI trajectory according to an example of the present disclosure.

In step 301, an RF pulse (e.g. RF pulse 411 of FIG. 4) is applied to a subject (e.g. a patient) in a static magnetic field in the presence of an applied spatial magnetic field gradient. The subject may be positioned on table 109, which has been placed into the bore of the MRI body 101, with reference to FIG. 1. The static magnetic field, B₀, is generated by primary magnet 103.

To select a slice (e.g. a portion of tissue of subject), a spatial, or gradient, magnetic field is applied by means of current provided to one or more gradient coils 105. Calibration of the RF pulse determines the depth and position of tissue, or slice, to be selected of the subject. Application of the RF pulse induces magnetic resonance in the nuclei of the slice.

At step 303, magnetic resonance, MR, signals (e.g. from the nuclei of the selected slice) are received. That is, following application of the RF pulse, the decay, or relaxation, of the magnetisation may be received as an electrical signal. An RF receiver may be used to receive the MR signals. In an example, the RF receiver may be integrated within RF control 113. In other examples, a separate RF receiver may be used.

At step 305, the MR signals are sampled corresponding to time to echo, TE, following application of the RF pulse. That is, whilst the MR signals are continuously sampled, TE corresponds to a time point of the (acquired, or generated) k-space of the EPI, volume.

As illustrated at FIG. 4, the signals may be sampled (i.e. at step 305) so as to acquire a plurality of temporarily adjacent EPI volumes, that is, temporarily successive volumes, or images, of the MR signals. A k space map is generated for the received signals over each of the received plurality of EPI volumes. That is, the sampled signals, which are taken over each of the EPI volumes, are recorded in k space (e.g. FIG. 4, 401, representing ky-t space, and FIG. 4, 403, representing k space). k space 403 thus comprises interleaved data across each of the plurality of EPI volumes.

To record (e.g. encode) the signals in k space 403, one or more gradients are applied when sampling the signals. A readout gradient, such as oscillating readout gradient 417, is applied along a plane of the selected slice. In an example, this may be an “x axis”, or a readout axis (in k space), wherein each trajectory line corresponds to one line of readout data. In other words a gradient is applied by one or more of the plurality of gradient fields so as to spatially encode the readout signals (i.e. frequency encoding) in k space.

Additionally, the sampled signals, taken over each of the EPI volumes, are recorded (e.g., encoded) in k space by application of a phase encoding gradient 415. That is, whilst sampling the signals, a phase encoding gradient 415 is applied along a plane of the selected slice, for example, in an axis that is perpendicular to the readout gradient, by means of one or more of the gradient magnetic fields 105. In an example, this may be applied along the “y” axis, or a phase encoding axis (in k space). As each “line”, or row in k space, is recorded by each application of the phase encoding gradient (in other words, each line differs by the difference in phase of the spin resulting from the gradient application), the scanning time is dependent on the number of readouts (at phase encoding gradient). In examples, as shown in sequence diagram 405, the phase encoding gradient 419 is synchronised (shown by blips 413, 415) on a rising/falling edge of the oscillating readout gradient 417. Application of the gradients during sampling (i.e. gradient control sequences 417, 419) define the trajectory by which data is recorded in k space.

FIG. 4 illustrates a multi-echo blip rewound EPI (ME-rEPI) trajectory of k space. That is, a plurality of echos (multi-echo), or EPI volumes, are obtained or acquired within a readout in k space.

As seen in diagrams 401, 403, the ME-rEPI trajectory (as controlled by means of application of the gradients during sampling) interleaves between the multiple EPI volumes. That is, the trajectory within k space fills or records data from alternate, or different, EPI volumes for each of the trajectory lines. Thus, the EPI volumes can be acquired in a single TR (e.g. single shot,), with ΔTE being twice that of the EPI echo spacing. In other words, the echo time difference, ΔTE, between a time to echo, TE, for each of the successive EPI volumes is twice the echo spacing, where the echo spacing is the time duration of the successive trajectory lines (successive ky encoding lines).

The multiple EPI volumes are temporarily adjacent, wherein each successive sampling point in k_{y}-t space 401 is obtained from a sequential EPI volume. That is, each of the successive sampling points represents a point from a different EPI volume (that is, a sampling point is obtained from each of the EPI volumes in turn). In ky-t space, 401, the ME-rEPI trajectory samples three straight lines of encoding points that are temporally adjacent to each other, e.g. in a zig-zag pattern. As shown in k-space, 403, this ME-rEPI trajectory traverses along the phase encoding direction (k_{y} axis) in a periodic rewinding pattern.

Referring to pulse sequence diagram 405, to perform the rEPI trajectory on an MRI scanner, periodic rewinder blips 415 are inserted between regular EPI blips 413 along the k_{y} phase encoding direction. In other words, the k_{y} phase encoding gradient is applied at a plurality of magnitudes (i.e. at least a first and second magnitude), so as to interleave the trajectory lines of readout data in k space throughout the acquisition of each image (EPI volume). The plurality of regular, or standard, EPI blips are each applied at the same magnitude (e.g. first magnitude), and the rewinder blip 415 at a different magnitude (e.g. second magnitude). The rewinder blip 415 is applied at a different polarity (e.g., to the polarity of the applied regular phase encoding gradient) as shown in the phase encoding gradient 419 of sequence diagram 405.

In the example trajectory shown, rewinder blip 415 is shown at a second amplitude that is larger than blip 413. This corresponds in ky-t space 401, or k space 403, to “rewind” between echoes e3 to e1.

It is noted that the interleaved trajectory shown in FIG. 4 is merely an example, and it will be appreciated that one or more patterns of interleaving may be defined by application of one or more amplitudes of the phase encoding gradient between readout lines of successively sampled EPI volumes. Such patterns of interleaving may at least partly be based on a number of EPI volumes (for example, 2-5 EPI volumes), wherein a larger number of EPI volumes (i.e. 4 or greater) may comprise the phase encoding gradient being varied between a first, second, and third magnitude. Various examples of such rewinder patterns which may be utilised are later discussed.

Based on the interleaved acquisition of multiple EPI images, the ME-rEPI trajectory de-couples the number of k_{y} encoding lines with TEs of later echoes (i.e. later EPI volumes) and ΔTE. In other words, the acquisition of the later EPI volumes does not depend on the completed acquisition of the earlier EPI volumes; the defined trajectory interleaves sampling of the successively obtained EPI volumes over time (e.g. k_{y}-t space). This allows for the acquisition of high-resolution EPI images without inducing a long TE (which may cause a SNR penalty on later echoes) and ΔTE (which may cause phase wrapping difficulties when analysing a generated image).

As noted, the trajectory illustrated in FIG. 4 is one example of ME-rEPI, and it will be appreciated that various trajectories for k space recordal may be performed, e.g., by means of the interleaved acquisition of multiple EPI volumes herein described.

Firstly, depending on the number of EPI volumes (otherwise, EPI images, or echoes) and echo time difference (ΔTE), different ME-rEPI trajectories can be designed. In examples, for each interleaved trajectory across the multiple EPI volumes acquired with a rEPI readout, the under-sampling factor should be identical, for consistency in distortion across multiple echoes, to provide for robust joint reconstruction. That is, the spacing in the phase encoding axis (k_{y}), based on the variation in magnitudes of the phase encoding gradient, should be the same between the k_{y} recordal lines for each of the individual EPI volumes.

Secondly, the ME-rEPI trajectory is designed such that there is no repeated acquisition for any k_{y} lines (e.g. a point in k_{y}-space is uniquely, or only, sampled once). In other words, the readout data for each of the plurality of EPI volumes is interleaved progressively over time, along k_{y}-t space. This improves the acquisition efficiency.

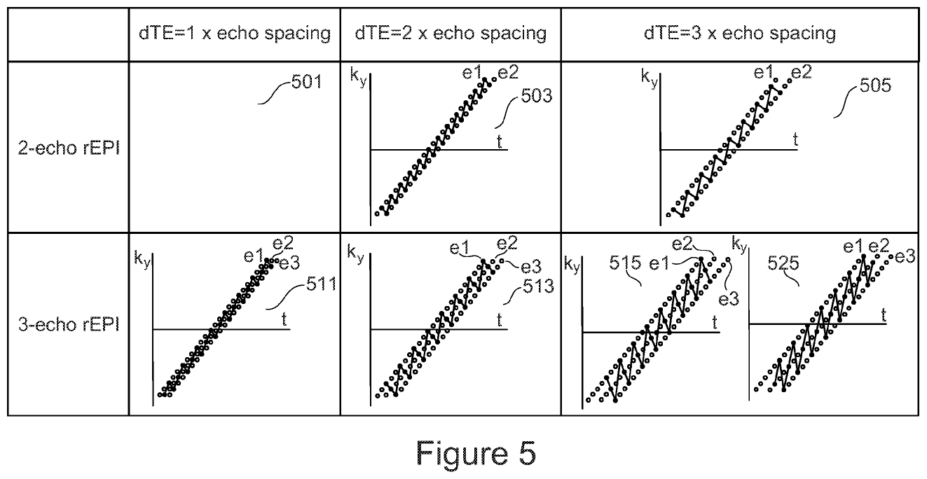

FIG. 5 illustrates ME-rEPI trajectories with 2 and 3 echoes (or EPI volumes) and different ΔTE (1/2/3×echo spacing), according to further examples of the present disclosure.

The ME-rEPI trajectories, similarly to FIG. 4, present examples of interleaved acquisition across multiple EPI volumes. It may be seen from the below described examples that the trajectories to be designed are based on the number of echos (EPI volumes), and the echo spacing therebetween, and according to the principles above.

Diagrams 501 and 511 illustrate ME-rEPI trajectories for 2 and 3 echos with 1×echo spacing. As indicated by diagram 501, for some configurations, there might be no available trajectory based on the two principles listed above (e.g., as for 2-echo rEPI with ΔTE=1×echo spacing).

Diagrams 503 and 513 illustrate ME-rEPI trajectories with 2× echo spacing for 2 and 3 echoes. For each example, one available trajectory is shown.

Diagram 505 shows an ME-rEPI trajectory for 2 echos and ΔTE=3×echo spacing. For other configurations, based on the two principles listed above, there can be more than one trajectory. For example, referring to diagrams 515, 525, (e.g., 3-echo rEPI with ΔTE=3×echo spacing), a number of trajectories are available. The different trajectories may therefore differ by the order, or sequence, in which each of the EPI volumes are sampled. That is, in diagram 515, e1 is sampled first, whereas in diagram 525, e2 is sampled first. In other examples, a third echo, e3, may be sampled first. It may be seen that the order in which the echoes are sampled may differ; however, each echo is sampled in turn.

Alternatively, or additionally, to obtain the different trajectories, the order in which the magnitudes of the phase encoding gradient are applied may differ. In some examples, a first magnitude and second magnitude of a phase encoding gradient may be applied. That is, in some examples, an initial first magnitude may be smaller (which may be a standard EPI blip), and a second magnitude may be larger (which may be a rewinder blip). However, in other examples, a first magnitude may be larger than the second magnitude, to provide the periodic rewinding pattern.

Whilst FIG. 5 illustrates 2 and 3 echo trajectories; the present disclosure is not limited as such, and further (i.e. additional) echoes, or EPI volumes, may be sampled. In examples, either 4 or 5 echo ME-rEPI may be traversed in k space by means of the methodology herein described. In these examples, the sampling of signals of 4 or 5 EPI volumes may be performed by the application of the phase encoding gradient at a first and second amplitude, as described. In other examples, the phase encoding gradient may be applied at a first, second and third amplitude, each of the first, second and third amplitude having different values. Herein, one of the first, second and third amplitude represents the rewinder blip, that is, having a different polarity.

It will be noted that the above-detailed examples are designed by reference to single-shot acquisition. Single-shot EPI may provide effective acquisition (e.g. by means of acquiring one image within a single-shot readout, which may be in less than 150 ms or so), which reduces motion sensitivity during acquisition. However, in other examples, the described method may be used with multi-shot acquisition.

The multiple EPI volumes (images) have very similar image contrast due to the short ΔTE, which can be leveraged in a joint reconstruction algorithm to improve the reconstruction of under-sampled data. A short ΔTE also reduces phase wrapping and facilitates robust field map estimation. Therefore, the ME-rEPI trajectory, in accordance with examples of the present disclosure, provides equivalent robustness against motion and respiration, as each B₀ field map is derived from a single-short readout with a short temporal duration (e.g. 20-50 ms). However, it will be appreciated that in some examples, the duration may be longer than 50 ms.

Detail on the joint reconstruction of acquired k space to generate an image will be described with reference to the following disclosure.

Referring back to FIG. 3, at step 307, the generated k space map is divided into a plurality of k space sub-maps, each of the plurality of k space sub-maps associated with one of the plurality of EPI volumes. That is, each one of the plurality of k space sub-maps corresponds to a sampled EPI volume (e.g. e1, e2, e3). As the sequential acquisition across EPI volumes is identical (that is, the pattern providing the interleaving of the trajectory lines), the spacing between trajectory lines of the respective EPI volumes is identical for EPI volume within k space.

Reconstructing each image separately using conventional parallel imaging can be prone to g-factor noise amplification and residual aliasing artefacts. However, due to the short echo spacing in ME-rEPI, the EPI images acquired in a ME-rEPI readout as described in the present examples are highly similar and there exists information redundancy between these images which can be leveraged to improve the reconstruction.

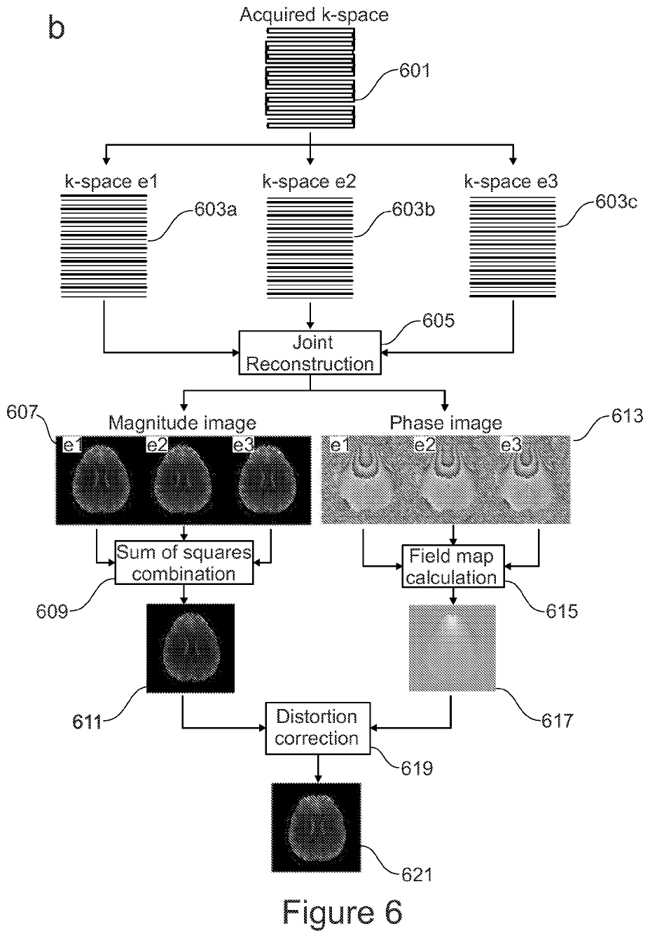

FIG. 6 illustrates a diagram illustrating joint reconstruction and distortion correction pipeline for ME-rEPI, according to an example of the present disclosure. In particular, FIG. 6 illustrates steps following generation of the k space map 601, e.g. following step 305 of FIG. 3. The generated k space map 601 is divided into a plurality of k space sub-maps 603a-c, each of the plurality of k space sub-maps associated with one of the plurality of EPI volumes (e.g. step 307 of FIG. 3).

Corresponding to step 309 of FIG. 3, the k-space sub-maps 601a-c may be jointly reconstructed by application of an optimisation function which utilises the shared information across the plurality of k space sub-maps 603a-c. The optimisation function may be solved (e.g. iteratively) across the plurality of k space sub-maps. It will be appreciated that a number of optimisation functions are known to the skilled person. The examples listed herein are therefore merely one such example of an optimisation function to be applied for joint reconstruction 605 of k space.

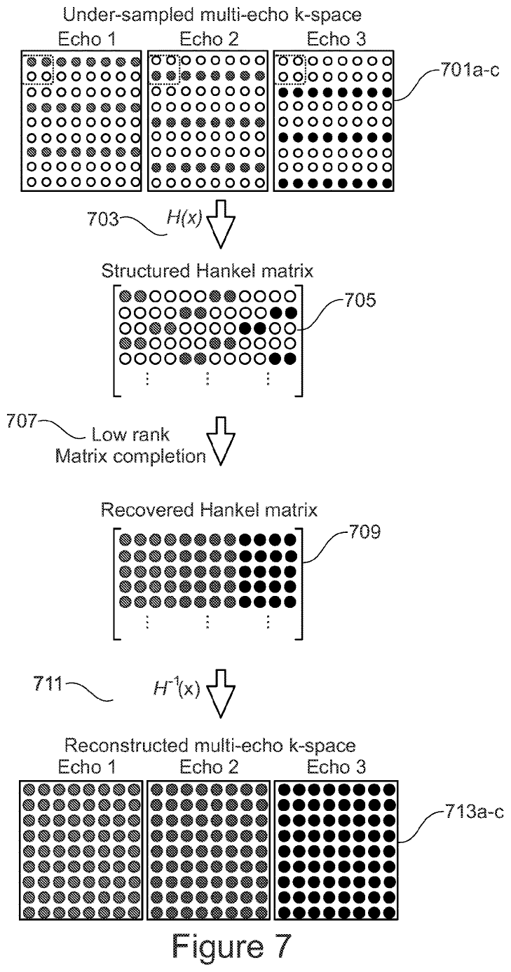

In an example, joint multi-echo reconstruction 605 may be based on low-rank Hankel structured matrix recovery that exploits the shared information across k-space sub-maps 603a-c that correspond to echoes e1-e3. An example of application of the low-rank structured matrix recovery for joint reconstruction based on low-rank Hankel structured matrix recovery is later described in detail with reference to FIG. 7.

In an example, based on joint reconstruction at step 605, a plurality of reconstructed k space maps, corresponding to each of EPI volumes, are obtained. By utilising the shared data, e.g. by leveraging the information redundancy between the similar EPI volumes, the under-sampled k-space (k space sub-maps) may be jointly reconstructed so as to obtain corresponding reconstructed k space maps for each of the EPI volumes (e.g. reconstructed k space maps 713a-c of FIG. 7).

Referring to FIG. 6, magnitude images 607 and phase images 613, are obtained from the reconstructed k space maps. The plurality of magnitude images 607 and phase images 613 each correspond to one of the respective EPI volumes.

It will be appreciated that images (e.g. MRI images or clinical scans) may be obtained (e.g. generated or recovered) from k-space using known techniques (e.g. Fourier transforms) for any of the examples herein described in the present disclosure.

At step 609, the plurality of magnitude images 607 are combined, e.g. by a sum of squares combination, to generate combined magnitude image 611. In other examples, the plurality of magnitude images may be combined by other suitable methods, e.g. complex summation, or phase corrected summation. At step 615, the plurality of phase images are combined, e.g. by a field map calculation, to generate a combined image (e.g. combined B₀ image) 617. The combined B₀ image 617 is indicative of an estimation of B₀ field offset of the static magnetic field.

Referring back to FIG. 3, at step 311, an image (e.g. final image) may be generated based on the reconstructed k space data (e.g. based on the reconstructed k space maps) following the joint reconstruction.

That is, in some examples, following joint reconstruction 605 (e.g. as provided in FIG. 7), a combined B₀ image 617 and combined magnitude image 611 are obtained, as set out at FIG. 6. At step 619 of FIG. 6, the combined magnitude image 611 is corrected in view of the field offset estimation (combined B₀ image 617) to generate an image 621 (e.g. image, or final image, at step 311).

This final image provides benefits in improved distortion correction (e.g. as arising from patient motion), reducing associated distortion artefact. Generated images can be used for measurement of dynamic variations of tissue parameters affecting local magnetic field fluctuations.

Referring to FIG. 7, FIG. 7 illustrates an example of application of low-rank structured matrix recovery for joint reconstruction that is based on a low-rank Hankel structured matrix recovery, according to an example of the present disclosure. Within FIG. 7, solid and hollow circles denote the acquired and unacquired k-space data, respectively.

Referring to FIG. 7, k-space sub-maps 701a-c may correspond to k-space sub-maps 603a-c, as described with reference to FIG. 6. Each of the k-space sub-maps is associated with one of the plurality of EPI volumes.

At step 703, the optimisation problem is formulated (or solved) across the plurality of k space sub-maps. In the example shown, the optimisation function (or problem) may be reformulated from a structured low rank matrix approximation. In some examples, as illustrated from steps 703-705, this may utilise a structured Hankel matrix (e.g. low-rank Hankel structured matrix recovery).

In an example, the reconstruction problem (e.g. structured low rank matrix approximation) may be formulated as:

$$x = {arg min}_{x} {‖ Ax - b ‖}_{{l}_{2}}^{2} \qquad Equation 1$$

$$s . t . rank ( H ( x ) ) = r$$

Where x (NₑN₁N₂×1) is the vector of the coil-combined k-space of multiple EPI image acquired with a single ME-rEPI readout, which needs to be reconstructed. N₁ and N₂ are the width of k-space along the readout and phase encoding dimensions, Ne is the number of EPI images. b (N₁N₂N_{c}/R×1) is the acquired multi-coil k-space data, Nc is the number of receive coils and R is the under-sampling factor applied along the phase encoding dimension. The operator A performs composite operation of M·F·S·F⁻¹, where F and F⁻¹ are Fourier transform and its inverse, S is coil sensitivity encoding and M denotes the k space sampling. H(x) is the block-Hankel structured matrix, shown at 705, forming from the multi-echo k-space data, which concatenates vectorized k space local patches from multiple echoes along the column dimension. r is the rank parameter of the block-Hankel structure matrix that needs to be pre-defined.

A number of numerical algorithms have been developed to solve structured low-rank constrained MRI reconstruction problems, each of which may be utilised in examples of the present disclosure. That is, each of the examples may utilise shared information (or information redundancy) to solve the reconstruction, in view of jointly reconstructing k space data. One example is described below.

Referring back to FIG. 7, at step 707, the low rank matrix is competed, and a recovered Hankel matrix is obtained at step 709.

A nonconvex formulation for structured low-rank constrained reconstruction is shown, e.g. using the recovered Hankel matrix. Herein, the constrained reconstruction described in Equation 1 is reformulated to an optimization problem (e.g. to solve, or optimise):

$$x = {arg min}_{x} {‖ Ax - b ‖}_{{l}_{2}}^{2} + λ J ( H ( x ) ) \qquad Equation 2$$

$$with$$

$$J ( X ) = {\sum }_{j > r} {σ}_{j}^{2} = {min}_{T : rank ( T ) \leq r} {‖ X - T ‖}_{F}^{2}$$

Where σⱼ is the j^{th} largest singular value of the matrix X. ∥·∥_{F} is the Frobenius norm. J(·) is a non-convex regularization that promotes a low rank property of the input matrix. λ is a regularisation parameter balancing the data consistency term and the low rank constraint term.

In an example, the optimisation function (or problem) detailed in Equation 3 is solved iteratively that jointly recovers the k-space data of all echoes. Therein, reconstructed k space data may be obtained, such as shown at reconstructed k-space maps 713a-c.

After image reconstruction, a B₀ map can be calculated. For three-echo rEPI with ΔTE=2×echo spacing, the calculation is:

$$Δ B ( r ) = \frac{{Φ}_{3} ( r ) - {Φ}_{1} ( r )}{8 π {t}_{es}} \qquad Equation 4$$

Where φᵢ(r) denotes the phase image of the i^{th} echo and tₑₛ is the EPI echo spacing.

Although reference of the detailed disclosure is described with reference to specific MRI applications (e.g. including, but not limited to, spin echo, gradient echo, sequences), it will be appreciated that the above-detailed methodology may apply to various sequences, or applications, of MRI which will be known to the skilled person. In particular, the detailed methodology is compatible with any excitation methods utilising MRI.

One application of the above-detailed disclosure (i.e. as described in the preceding Figures) may be in integration of chemical shift based water-fat separation using spin echo diffusion weighted EPI. That is, the above-detailed disclosure may be applied so as to generate a water-fat image, and/or individual water and fat images.

In some examples, the methods described in the examples of the disclosure may be applied to obtain images (e.g., water-fat, water, and/or fat images) of breast, or prostate, tissues. Further examples and/or applications of the above-described methods may be used to obtain images of other organs and/or tissues.

Integration of chemical shift based water-fat separation with EPI readout have been developed, mainly for spin echo diffusion weighted EPI. By acquiring spin-echo based EPI with three different echo times, separate water and fat images can be obtained. The water-only images generated from this approach have less residual fat signal compared to using conventional fat saturation techniques. However, these techniques require longer (triple or longer) scan times due to the requirement of known processing techniques (e.g. Dixon or IDEAL processing), which limits the number of diffusion directions that can be acquired for a given scan time.

A rapid fat imaging method with a single-shot acquisition may improve robustness against subject motion and the accuracy of fat quantification.

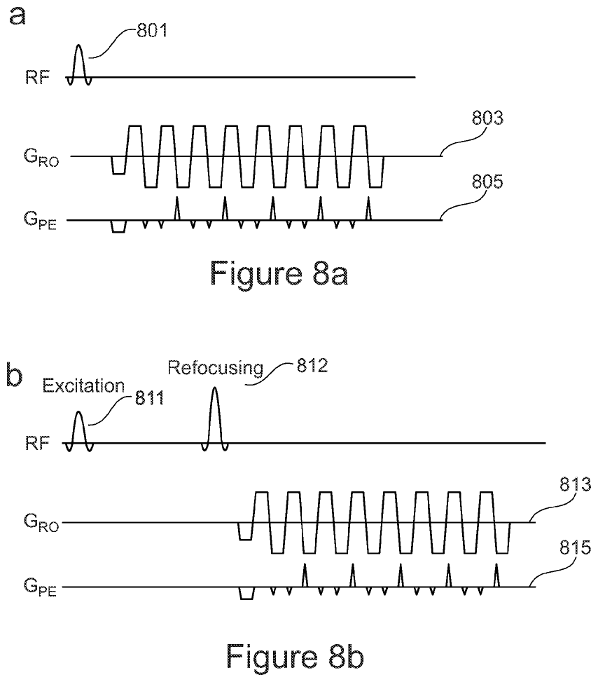

FIG. 8a illustrates a pulse sequence diagram for gradient-echo rEPI, which may be used in various applications in accordance with the present disclosure.

FIG. 8b illustrates a pulse sequence diagram for spin-echo rEPI, as may be used in various applications in accordance with the present disclosure. For example, the spin-echo rEPI may be used for a water-fat imaging application according to examples of the present disclosure. In particular, the capability of the rEPI trajectory, as described, to acquire multiple echoes with different TEs provides application of the method for use with single-shot water fat imaging.

By acquiring spin-echo signal with the proposed rEPI readout, multiple echoes with different echo times can be acquired in a single TR. This allows single-shot water-fat imaging, which improves efficiency of EPI based water-fat imaging while minimising its sensitivity to subject motion.

An example of the spin-echo signal, for use in the application of water-fat imaging, is illustrated in FIG. 8b (by comparison to gradient echo illustrated in FIG. 8a).

Referring to FIG. 8a, a gradient echo rEPI sequence is shown. Herein, the rEPI illustrated may correspond to the interleaved trajectory as illustrated at FIG. 4 and FIG. 5, as described. That is, following application of RF pulse 801, an interleaved trajectory through k space is acquired across a plurality of EPI volumes, by means of readout and phase encoding gradients, 803 and 805.

Referring to FIG. 8b, the rEPI sequence described in examples of the present disclosure, may be utilised with spin-echo imaging. Herein, a second RF pulse 812 (refocusing pulse) is transmitted to the subject in the static magnetic field. The second RF pulse 812 is transmitted at a time between (e.g. midway, or halfway) between transmitting the first RF pulse 811 and sampling the MR signals. In other words, the second RF pulse is transmitted at a time TE/2. Following transmittal of the second RF pulse 812, the MR signals may be sampled. The sampling of MR signals may be performed in accordance with FIG. 3, step 305, and by design of the one or more trajectories defined in the preceding examples.

Following the generation of the k space map for the plurality of EPI volumes (step 305), an image can be generated by jointly re-constructing the k space data, as described with reference to the preceding examples. In some examples, this may be as described in steps 307-311 of FIG. 3 and described examples, to generate an image.

Therefore, following a spin echo excitation, as illustrated in FIG. 8b, multiple EPI volumes (e.g. as shown with reference to FIG. 4 or 5) acquired can be used for single-shot chemical shift based water-fat imaging. This approach can produce a water image and a fat image simultaneously in a single readout with a duration of ~100 ms.

Water and fat images (e.g. water-fat imaging) may be obtained with reference to one or more of the examples listed below.

In an example, acquisition of data and joint reconstruction of said data may be described in the steps described above (e.g. with reference to FIG. 3, steps 303-311, following transmission of the second RF pulse). The generated image (e.g. at step 311) may represent MR signals comprising both water and fat information. In an example, one or more post processing techniques may be performed so as to obtain separate water and fat images. Such post processing techniques will be known to the skilled person, and, in some examples, may include Dixon or IDEAL processing.

In another example, following transmission of the second RF pulse, data acquisition may be the same as described with reference to steps 303-307. That is, such as described at step 307, a plurality of k space sub maps (e.g. as described with reference 603a-c) are obtained that are each associated with one of a plurality of EPI volumes. Each of these EPI volumes comprises information (that is composite MR signals) representing water and fat information (water and fat signals) of the subject.

In this example, applying the optimisation function so as to jointly reconstruct k space data is performed by means of a modified reconstruction algorithm to that described above (e.g. with reference to FIG. 7).

Referring to Equation 2, above, representing a reformulated optimisation problem (or function); the unknown value x within this equation, may be replaced with a specific signal model parameterised with water signal, fat signal, echo times, B0 field map, and R2* map. The signal model-based algorithm may be based on one or more parameters, including water and fat signal parameters, as described below with reference to Equation 5.

Thus the signal model-based reconstruction algorithm as described may be solved, or optimised, to jointly reconstruct k space data. That is, the reformulated optimisation problem may be formulated as a model-based reconstruction.

In the example, alternatively to the first example, water and fat images may be directly estimated (or herein obtained, or generated) from k space data, by means of incorporation of water and fat signal in the reconstruction algorithm, as defined.

In some examples, the model-based reconstruction may be formulated as:

$$\{ {I}_{water} , {I}_{fat} , {R}_{2}^{*} , {f}_{B 0} \} = {arg min}_{{I}_{water} , {I}_{fat} , {R}_{2}^{*} , {f}_{B 0}} {‖ {\sum }_{n} ( {A}_{n} F ( {I}_{water} + {I}_{fat} {\sum }_{m} {a}_{m} {e}^{i 2 π {f}_{m} {TE}_{n}} ) {e}^{- {R}_{2}^{*} Δ {TE}_{n}} {e}^{i 2 π {f}_{B 0} Δ {TE}_{n}} - {b}_{n} ) ‖}_{{l}_{2}}^{2} \qquad Equation 5$$

$$s . t . rank ( H ( x ) ) = r$$

$$\text{?}$$

Where I_{water}(N₁N₂×1) and Ifat (N₁N₂× 1) are water and fat signals, respectively. fₘ is the mth fat spectrum peak frequency, and am is the amplitude, which could be obtained in a separate calibration scan, by a self-calibration process or estimated prior to the reconstruction. The quantitative map of R₂*(N₁N₂×1) and B₀ field map f_{B0}(N₁N₂×1) is also incorporated in the model. n is the index of echoes ranging from 1 to Nₑ. N₁ and N₂ are the width of k-space along the readout and phase encoding dimensions, Nₑ is the number of EPI images. bₙ (N₁N₂N_{c}/(RNₑ)×1) is the acquired multi-coil k-space data, N_{c} is the number of receive coils and R is the under-sampling factor applied along the phase encoding dimension. ΔTEₙ is the TE shift for the echo n. The operator Aₙ performs composite operation of Mₙ·F·S·F⁻¹, where F and F⁻¹ are Fourier transform and its inverse, S is coil sensitivity encoding and Mₙ denotes the k space sampling for the echo n. H(x) is the block-Hankel structured matrix forming from the multi-echo k-space data, which concatenates vectorized k space local patches from multiple echoes along the column dimension. r is the rank parameter of the block-Hankel structure matrix that need to be pre-defined.

In further examples, using the model-based reconstruction, water and fat images may be obtained directly form the k space data (e.g. from the acquired k space in accordance with step 305, and the trajectory examples described therein). That is, as the modified reconstruction algorithm already utilises shared data (or shared information) across the EPI volumes (or echos), the generation of water and fat images may be generated directly from the acquired k space (e.g. generated k space map 601) by means of applying said reconstruction algorithm.

In further examples (such as in one of the examples above) utilising the model-based reconstruction, the low-rank Hankel structured matrix constraint may or may not be applied. In this latter case, it may be seen that the model based reconstruction as described has already exploited the correlation between echo images. That is, the shared information between the EPI images has been utilised by (that is, within) the model-based reconstruction.

As will be appreciated by means of the above-described examples, generation of the water and fat images is based on utilising shared information across acquired k space. That is, the generated images (e.g. water and fat images) may be obtained by application of an optimisation function utilising shared information across acquired (generated) sub-maps to jointly reconstruct data.

According to the examples described in the described application, robust fat saturation using EPI can be attained. By acquiring spin-echo signal with the described rEPI readout (trajectory), multiple echoes with different echo times can be acquired using a single readout. This provides single-shot water-fat imaging, which improves efficiency of EPI based water-fat imaging while minimising its sensitivity to subject motion.

Examples of applications of the present disclosure will be described with reference to the Figures below.

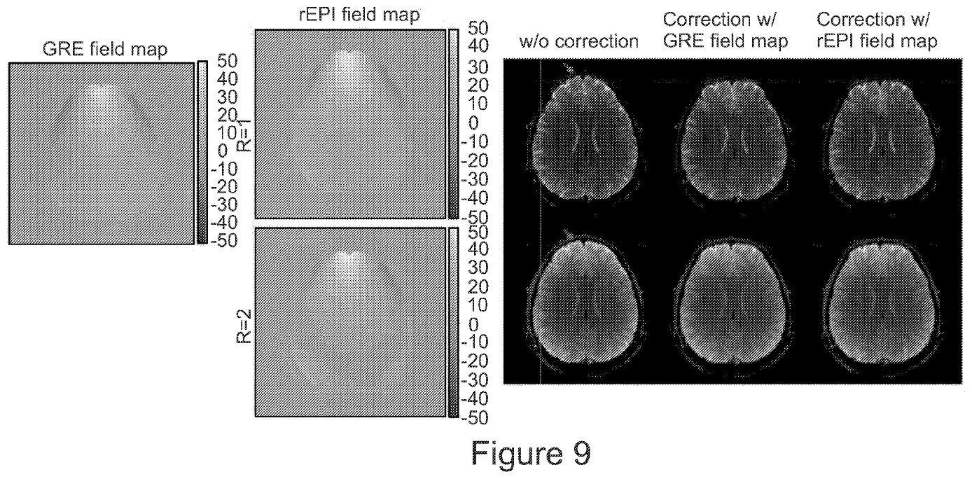

FIG. 9 illustrates field and magnitude maps of an axial slice acquired using a conventional gradient echo, GRE, based field mapping method and ME-rEPI based field mapping method according to an example of the present disclosure.

As shown in FIG. 9, rEPI generated field maps are highly similar to the field map measured using a reference GRE sequence, with consistent spatial patterns present in all field maps. Image distortions are effectively corrected using rEPI produced field maps, demonstrating the high accuracy of rEPI based field mapping.

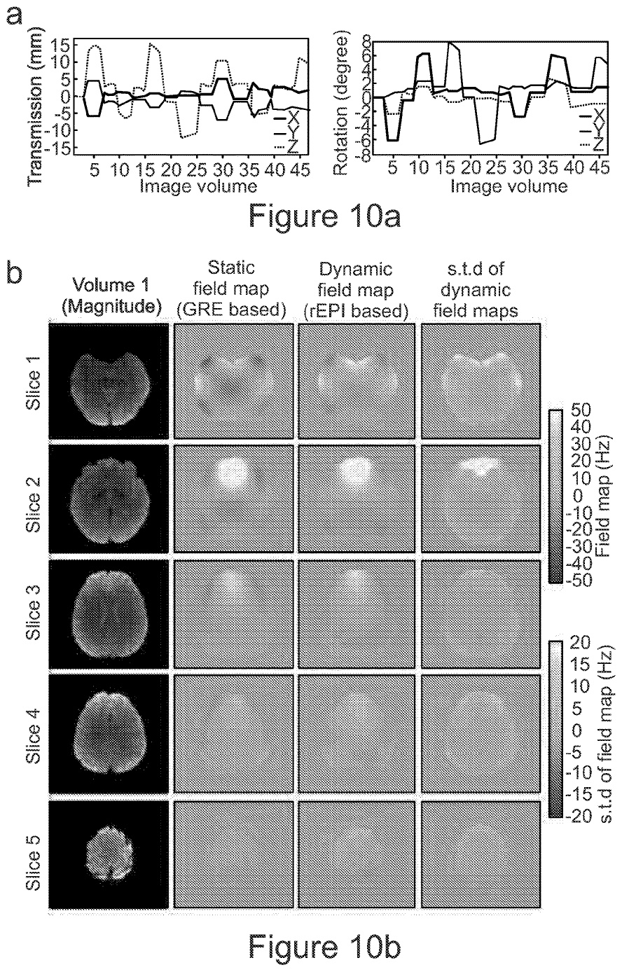

FIG. 10a illustrates translation and rotation motion during the MRI scan. FIG. 10b illustrates a comparison of field map estimation using a conventional gradient multi-echo, GRE, based method (static approach) and rEPI method (dynamic approach). The field map of the first volume and the standard deviation (s.t.d) of the dynamic field map from rEPI are displayed. The standard deviation (s.t.d) of the dynamic field map from rEPI indicates high variations, particularly in the frontal areas at lower slices, which is not captured using conventional static field mapping method.

In the presence of subject motion (FIG. 10a), the B₀ field can vary substantially over time, particularly in regions at lower slices and near the frontal area (FIG. 10b). These variations can be measured using rEPI due to its capability of dynamic field mapping, which is not possible with GRE based static field mapping.

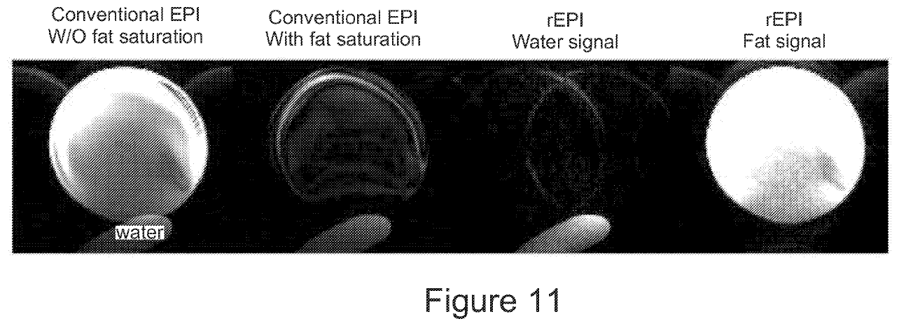

FIG. 11 illustrates conventional fat suppression and fat water imaging using spin-echo rEPI. A spherical oil phantom and a water tube were imaged in the same FOV. From left to right: conventional EPI without fat suppression, where both fat and water signal are visible; conventional EPI with fat suppression, where fat signal is just partially suppressed due to limitations of the conventional fat suppression technique; water image from rEPI based water-fat imaging; fat image from rEPI based water-fat imaging.

FIG. 11 compares conventional fat suppression method with rEPI based water fat separation. Due to the sensitivity to B0 and B1 inhomogeneity, conventional fat suppression method cannot effectively remove fat signal. This is shown in the second column of FIG. 11, where a lot of signal of the fat phantom is still visible even after the fat saturation.

The water-image using rEPI based water-fat imaging method can be seen to provide a better suppression of fat signal, as shown in column 3 of FIG. 11, where most fat signal is suppressed. In addition, with rEPI based water-fat imaging, a fat-only image can be obtained using a single-shot readout, as shown in the fourth column of FIG. 11.

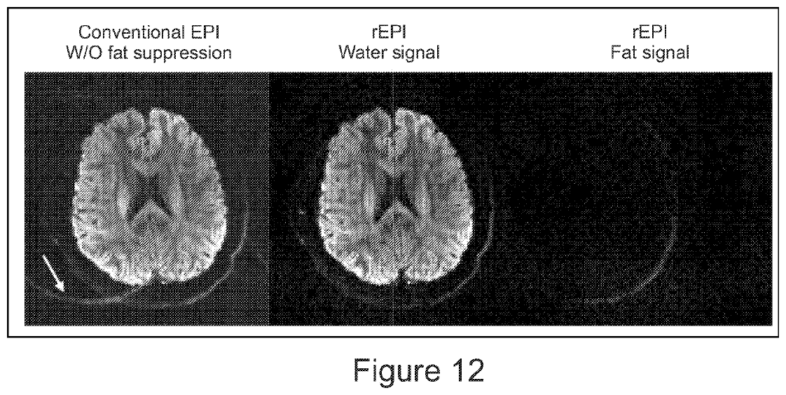

FIG. 12 illustrates a comparison of conventional fat suppression and water-fat imaging using single-shot rEPI.

In particular, the example of FIG. 12 illustrates a comparison of conventional EPI and rEPI based fat-water separation, where the data was obtained in vivo. Referring to the left to right images of FIG. 12: left image shows conventional EPI without fat suppression, where both fat and water signal are visible. Due to the low bandwidth along the phase encoding direction (left-right), the fat signal is shifted relative to the water signal (white arrow); the middle image shows water image from rEPI based water-fat imaging, where the fat signal is removed; and the right image shows fat image from rEPI based water-fat imaging.

To obtain the data shown in FIG. 12, one subject was scanned to evaluate the performance of rEPI based water-fat separation. Two datasets were acquired: conventional single-shot EPI without fat saturation, and single-shot 3-echo rEPI without fat saturation. Scan parameters for conventional single-shot EPI: FOV 220 mm×220 mm×100 mm, resolution 2.2 mm×2.2 mm×2 mm, TR=7 s, echo spacing 0.65 ms, no in-plane acceleration, phase encoding direction is left-right. Scan parameters for rEPI are the same as conventional single-shot EPI, but with a shorter TR=6.4 s. The echo time difference between two consecutive echoes in rEPI is 1.3 ms.

With reference to the above-detailed examples, it will be appreciated that features, integers, characteristics, compounds, or groups described in conjunction with a particular aspect, embodiment or example of the present disclosure are to be understood to be applicable to any other aspect, embodiment or example described herein unless incompatible therewith. All of the features disclosed in this specification (including any accompanying claims, abstract and drawings), and/or all of the steps of any method or process so disclosed, may, in examples, be combined in any combination, except combinations where at least some of such features and/or steps are mutually exclusive. In addition, the present disclosure is not restricted to the details of any foregoing embodiments, and extends to any novel one, or any novel combination, of the features disclosed in this specification (including any accompanying claims, abstract and drawings), or to any novel one, or any novel combination, of the steps of any method or process disclosed.

It will be appreciated that various functions described herein (e.g., in combination with any embodiment or example of the present disclosure, for example, the methods described above) can be implemented or supported by one or more computer programs, each of which is formed from computer readable program code and embodied in a computer readable medium. The terms “application” and “program” herein refer to one or more computer programs, software components, sets of instructions, procedures, functions, objects, classes, instances, related data, or a portion thereof, adapted for implementation in a suitable computer readable program code.

1. A method of image generation using magnetic resonance imaging, MRI, with echo-planar imaging, EPI, comprising:
transmitting a RF pulse to a subject in a static magnetic field in the presence of an applied spatial magnetic field gradient;
receiving magnetic resonance, MR, signals;
sampling the received MR signals to acquire a plurality of temporarily adjacent EPI volumes and generating a k space map for the plurality of EPI volumes by:
applying an oscillating readout gradient over each of the plurality of EPI volumes to obtain readout data along a readout axis; and
applying a phase encoding gradient, while applying the oscillating readout gradient, such that trajectory lines of readout data for each of the plurality of EPI volumes are interleaved in k space using a periodic rewinding pattern along a phase encoding axis;
dividing the generated k space map into a plurality of k space sub-maps, each of the plurality of k space sub-maps associated with one of the plurality of EPI volumes,
applying an optimisation function utilising shared information across the plurality of k space sub-maps to jointly reconstruct k space data; and
generating an image based on the jointly reconstructed k space data.

2. The method of claim 1, wherein applying the phase encoding gradient further comprises:
synchronising the phase encoding gradient on each of a rising and falling edge of the oscillating readout gradient.

3. The method of claim 1, wherein applying the phase encoding gradient further comprises:
varying an amplitude of the phase encoding gradient between a first amplitude and second amplitude so as to interleave the trajectory lines of the readout data of each of the plurality of EPI volumes in k space,
wherein the first and second amplitude of the phase encoding gradient have a different polarity.

4. The method of claim 3, wherein the second amplitude is larger than the first amplitude.

5. The method of claim 3, wherein the first amplitude is larger than the second amplitude.

6. The method of claim 3, wherein applying the phase encoding gradient further comprises:
varying the amplitude of the phase encoding gradient between the first amplitude, second amplitude and a third amplitude so as to interleave the trajectory lines of the readout data of each of the plurality of EPI volumes in k space,
wherein the third amplitude is a different amplitude to the first and second amplitude.

7. The method of claim 1, wherein:
the periodic rewinding pattern is repeated across each of the individual EPI volumes, such that trajectory lines of readout data corresponding to each of the individual EPI volumes have a same spacing along the phase encoding axis;
the periodic rewinding pattern comprises uniquely sampling from each of the plurality of EPI volumes; and/or
the periodic rewinding pattern for interleaving the trajectory lines is based on
a number corresponding to the plurality of acquired temporarily adjacent EPI volumes, and
an echo time difference, ΔTE, corresponding to a time to echo difference for two temporarily adjacent EPI volumes within the plurality of EPI volumes.

8-9. (canceled)

10. The method of claim 9, wherein the echo time difference, ΔTE, between two temporarily adjacent EPI volumes is a multiple value of echo spacing between the temporarily adjacent EPI volumes,
wherein echo spacing is a time duration between successively obtained trajectory lines of readout data.

11. The method of claim 10, wherein the plurality of EPI volumes comprises 2-5 EPI volumes, or
wherein when the plurality of EPI volumes comprises 2 EPI volumes, the multiple value is one of: 2 or 3.

12. (canceled)

13. The method of claim 10, wherein:
when the plurality of EPI volumes comprises 3 EPI volumes, the multiple value is one of: 1, 2 or 3.

14. The method of claim 1, wherein applying the optimisation function comprises:
solving the optimisation function across the plurality of k space sub-maps to jointly reconstruct k space data.

15. The method of claim 14, wherein the optimisation function is iteratively solved across the plurality of k space sub maps.

16. The method of claim 14, wherein the optimisation function is reformulated from a structured low rank matrix approximation.

17. The method of claim 1, further comprising:
transmitting a second RF pulse to the subject in the static magnetic field in the presence of the applied spatial magnetic field gradient,
wherein the second RF pulse is transmitted at a time between transmitting the RF pulse and sampling the MR signals.

18. The method of claim 17, wherein, the generated image comprises water and fat signals of the subject; and
applying post processing to generate separate water and fat images.

19. The method of claim 1, further comprising:
based on the jointly reconstructed k space data, acquiring a plurality of reconstructed k space maps each representing an EPI volume and
generating the image based on the jointly reconstructed k space maps.

20. The method of claim 19, wherein generating the image comprises:
generating, from the plurality of reconstructed k space maps, a plurality of magnitude images and phase images that each correspond to one of the respective EPI volumes;
combining the plurality of magnitude images to generate a combined magnitude image; combining the plurality of phase images to generate a combined image indicative of an
estimation of field offset of the static magnetic field; and
correcting the combined magnitude image in view of the field offset estimation to generate the image.

21. The method of claim 17, wherein applying the optimisation function across the plurality of k space sub-maps comprises:
solving the optimisation function by applying a signal model-based reconstruction algorithm that utilises shared information across the plurality of k space sub-maps to jointly reconstruct k space data;
wherein the signal model is based on water and fat signal parameters; and generating water and fat images based on the applied reconstruction.

22. A system for image generation for magnetic resonance imaging, MRI, using echo-planar imaging, EPI, the system comprising an MRI device and computing device, and the system configured to perform the method according to claim 1.

23. A computer program comprising instructions which, when the program is executed by a computer or processor, causes the computer or processor to carry out a method according to claim 1; optionally the computer program is stored on a computer readable medium.
